(19) United States
(12) Patent Application Publication
(10) Pub. No.: US 2026/0182390 A1
(43) Pub. Date: Jun. 25, 2026

(54) 3D CIRCUIT ON SOLID RF SUBSTRATE

(71) Applicant: COMMISSARIAT A L'ENERGIE ATOMIQUE ET AUX ENERGIES ALTERNATIVES, Paris (FR)

(72) Inventors: Perrine BATUDE, Grenoble Cedex (FR); Thibaud FACHE, Grenoble Cedex (FR); Blandine DURIEZ, Grenoble Cedex (FR); Didier BELOT, Grenoble Cedex (FR); Pascal LE CHEVALIER, Grenoble Cedex (FR); Daniel GLORIA, Grenoble Cedex (FR)

(73) Assignee: COMMISSARIAT A L'ENERGIE ATOMIQUE ET AUX ENERGIES ALTERNATIVES, Paris (FR)

(21) Appl. No.: 19/425,108

(22) Filed: Dec. 18, 2025

(30) Foreign Application Priority Data
Dec. 20, 2024 (FR) FR2414887

(51) Int. Cl. H10W 44/20; H10D 80/30; H10D 84/01; H10D 84/40; H10D 84/82; H10P 30/22; H10W 72/00; H10W 90/00

(52) U.S. Cl. CPC H10W 44/248; H10D 80/30; H10D 84/0109; H10D 84/401; H10D 84/82; H10P 30/22; H10W 72/07331; H10W 90/732

(57) ABSTRACT

Aspects of the present disclosure provide an integrated circuit on a bulk semiconductor substrate, including a bulk semiconductor substrate, opposite a first region of the substrate, at least one transistor of a lower level of transistors, formed in a first semiconductor layer belonging to the bulk semiconductor substrate or disposed on and in contact with said substrate, at least one transistor of an upper level of transistors having a channel region in a second semiconductor layer arranged in a stack of layers resting on the substrate, the upper-level transistor being disposed opposite a second region, one or more metal interconnection levels and at least one RF component such as an antenna formed in a given level out of said metal interconnection levels, the RF component being arranged opposite a localized structure for trapping charges and/or blocking stray voltages.

### TECHNICAL FIELD AND PRIOR ART

The field of the invention is that of microelectronic devices formed on substrates adapted to radiofrequency (RF) uses.

The invention relates more particularly to a 3D microelectronic device formed on a bulk substrate provided with a heterogeneous surface zone to make it adapted to both RF uses and the integration of particular transistors having optimized performance, in particular bipolar transistors.

For RF uses, and in particular those operating at a high frequency and typically above 700 MHz, the substrates must act as a support for the circuits without disturbing the operation thereof. In particular, it is sought to eliminate propagation losses, crosstalk or parasitic harmonics.

Substrates of the semiconductor-on-insulator type adapted for these RF uses exist, in particular those of the RF-SOI type (SOI for “Silicon On Insulator”).

A substrate of the semiconductor-on-insulator type is commonly formed by a support semiconductor layer covered by, and in contact with, an insulating layer, itself covered by, and in contact with, a semiconductor surface layer generally intended to be used as an active layer, that is to say in which active components, such as transistors or passive components, in particular of an RF circuit, are intended to be formed.

For RF uses, known adaptations of these substrates consist in:
providing a support layer made of weakly doped resistive semiconductor material and,
forming under and against the insulating layer commonly called “BOX” a charge-trapping layer commonly called “trap rich”. This is a layer formed by a semiconductor material rich in crystalline defects and/or grain joints and which allows to trap charges. Without this trapping layer, fixed (positive) charges in the BOX would lead to the presence of mobile charges (electrons) in the support layer in the vicinity of the BOX, locally canceling out the benefit of the weak doping of the support layer. The trapping layer is usually formed by a layer of polycrystalline silicon.

For some specific uses in which it is also sought to have transistors capable of handling high current levels, in particular bipolar transistors, RF-SOI substrates can have limitations in terms of density and performance.

RF-SOI substrates also turn out to be particularly expensive.

Other types of substrates are now used for RF uses, in particular substrates made of glass, quartz and ceramic.

“High resistivity” (HR) bulk substrates can also be used for RF uses.

Such substrates are not always adapted to an integration with a high density of components.

Furthermore, the presence of unintentional impurities can have a significant effect on the electrical properties of the HR semiconductor material, potentially becoming sources of disturbances.

The problem arises of creating a microelectronic device on such a type of substrate that has an improved integration density while preserving good performance with respect to possible disturbances related to an RF circuit and/or component(s).

### DISCLOSURE OF THE INVENTION

It is therefore a goal of the present invention to provide an integrated circuit on a bulk semiconductor substrate comprising:
a bulk semiconductor substrate, in particular highly resistive,
a lower level of transistors comprising, facing a first region of the substrate, at least one lower-level transistor, the lower-level transistor being formed at least partially in a first semiconductor layer, the first semiconductor layer belonging to the bulk semiconductor substrate and/or being disposed on and in contact with the substrate,
an upper level of transistors provided with at least one upper-level transistor having a channel region in a second semiconductor layer arranged in a stack of layers resting on the substrate, said upper-level transistor being disposed facing a second region of the bulk substrate,
a localized structure, for trapping charges and/or blocking stray voltages, formed on or in the second region of the substrate and configured to limit parasitic conduction in the second region of the substrate, the localized structure being located under the at least one transistor of the upper level,
one or more metal interconnection levels, and
at least one RF component such as an antenna or an inductance formed in a given level out of the metal interconnection levels, the RF component being arranged facing the localized structure for trapping charges and/or blocking stray voltages.

By providing such an arrangement, it is possible to simultaneously integrate transistors into the bulk substrate, preserve a good integration density of the transistors while protecting against the losses related to the substrates and undesirable effects of the stray capacitance, harmonic distortions and crosstalk type.

The structure for trapping charges and/or blocking stray voltages is preferably located only on or in the second region of the substrate.

Thus, the transistor of the first type, located in the first region, is not in contact with the structure for trapping charges and/or blocking stray voltages located on or in the second region of the substrate.

The localized structure configured to limit a stray conduction in the second region can comprise at least one element out of:
a layer of semiconductor material comprising implantation defects;
a layer of amorphous or polycrystalline semiconductor material;
a set of junctions formed by an alternation of zones doped according to a first type of doping, N or P, and zones doped according to a second type of doping, P or N, different from the first type of doping;
a heterogeneous dielectric region formed by an alternation of blocks of dielectric material with positive fixed charges and blocks of dielectric material with negative fixed charges.

Advantageously, the lower-level transistor is a transistor of a first type, while the upper-level transistor is a transistor of a second type.

The lower-level transistor opposite the first region can in particular be a bipolar or HEMT transistor.

The upper-level transistor opposite the second region can in particular be a MOS transistor, advantageously a MOS transistor with a partially or fully depleted channel.

Advantageously, the upper-level transistor is a transistor of a switch circuit, the switch circuit being disposed opposite the second region and preferably not extending opposite the first region.

According to one embodiment, the integrated circuit comprises at least one second upper-level transistor having a channel in the second semiconductor layer, this second upper-level transistor being at least partially arranged opposite the first region of the substrate.

According to a specific embodiment, the upper-level transistor can be provided with a rear electrode, in particular a ground plane, the rear electrode being arranged in said stack between the first region and said second upper-level transistor.

According to another aspect, the present invention relates to a method for manufacturing an integrated circuit as defined above.

An embodiment of the present invention relates to a method for manufacturing an integrated circuit comprising steps of:
providing a bulk substrate, in particular highly resistive (HR), and forming opposite a first region of said bulk substrate at least one lower-level transistor, the lower-level transistor having a channel in a semiconductor layer of the substrate and/or disposed in contact with said substrate,
forming opposite a second region of said substrate distinct from the first region a localized structure for trapping charges and/or blocking stray voltages to limit a stray conduction in the second region,
coating said lower level and said localized structure with at least one “inter-level” insulating layer,
assembling, in particular by molecular adhesion bonding, a support onto said inter-level insulating layer, said support being provided with a semiconductor layer called “second semiconductor layer”,
forming at least one upper-level transistor from said second semiconductor layer, said upper-level transistor having a channel region in the second semiconductor layer and being disposed opposite the second region of said substrate.

Advantageously, the formation of said at least one lower-level transistor comprises one or more steps carried out before the creation of said localized structure.

According to one implementation possibility, the method can comprise the creation of a masking on the second region to protect the second region, this masking being created so as to preserve an opening opposite the first region, the transistor being at least partially formed in the opening.

According to a specific implementation, the method can comprise the formation of at least one layer covering the lower-level transistor and a passage passing through said at least one layer covering the lower-level transistor, so as to expose said second region, the localized structure being then formed through the passage on or in at least a portion of the second region exposed by the passage.

According to one embodiment, the formation of the localized structure can comprise steps of:
depositing a layer of amorphous or polycrystalline semiconductor material in the hole or passage and so as to cover at least a portion of the second region, then
etching the layer of amorphous or polycrystalline semiconductor material so as to preserve at least a portion of amorphous or polycrystalline semiconductor material opposite the second region.

According to one possible implementation of the method in which the localized structure comprises a heterogeneous dielectric region formed by an alternation of blocks made of a dielectric material having positive fixed charges and blocks made of a second dielectric material having negative fixed charges, the formation of the localized structure can comprise steps of:
depositing in the hole or passage a first dielectric material, having positive fixed charges or having negative fixed charges, then
etching the first dielectric material so as to form blocks containing the first dielectric material, then
depositing a second dielectric material forming blocks containing the second dielectric material, the second dielectric material having positive fixed charges when the first dielectric material has negative fixed charges or having negative fixed charges when the first dielectric material has positive fixed charges.

According to one possible implementation of the method in which the localized structure comprises a plurality of juxtaposed junctions formed by an alternation of zones doped according to a doping of a first type, in particular P or N and zones doped according to a doping of a second type, in particular N or P and different from the first type, the method comprises a plurality of dopant implantations of the second region through the hole or a plurality of successive dopant implantations of the second region through the passage.

According to a specific embodiment, the localized structure can be formed by a charge-trapping layer, the creation of which comprises at least one amorphization implantation of a zone of the substrate arranged under the masking, the amorphization implantation being advantageously carried out after formation of the lower-level transistor.

According to another specific embodiment, the formation of the localized structure comprises an implantation leading to the formation of a layer rich in crystalline defects of a zone of the substrate arranged under the masking.

According to one embodiment, prior to the assembly between the substrate and the support, and after having coated the lower level and the localized structure with at least one “inter-level” insulating layer, the method can comprise the following steps:
forming one or more ground plane zones on said inter-level insulating layer, then
coating said one or more ground plane zones with at least one bonding insulating layer, the assembly of the substrate and the support being carried out subsequently by molecular adhesion bonding of the bonding insulating layer with the support assembled on said inter-level insulating layer.

### BRIEF DESCRIPTION OF THE DRAWINGS

The present invention will be better understood on the basis of the following description and the appended drawings in which:

FIG. 1 is used to illustrate an example of an integrated circuit with several levels of transistors and formed on a bulk substrate provided with a modified region, adapted for RF uses by allowing to block the circulation of stray voltages, and another region having a different and preferably unmodified composition adapted for other uses in particular those using bipolar transistors.

FIG. 2 is used to illustrate an embodiment of the circuit in which the region adapted for RF uses is formed by a charge-trapping layer.

FIG. 3 is used to illustrate a specific embodiment of the circuit in which the charge-trapping layer is formed by a zone implanted in the substrate and opposite which at least one RF component is disposed.

FIG. 4 is used to illustrate a specific embodiment of the circuit in which the charge-trapping layer is formed by a layer deposited on the substrate and opposite which at least one RF component is disposed.

FIG. 5 is used to illustrate a specific embodiment of the circuit in which the modified region of the substrate comprises an alternation of P-doped regions and N-doped regions and opposite which at least one RF component is disposed.

FIG. 6 is used to illustrate a specific embodiment of the circuit in which the modified region of the substrate comprises an alternation of blocks of dielectric material having positive charges and blocks of dielectric material having negative charges and opposite which at least one RF component is disposed.

FIGS. 7A and 7B are used to illustrate various examples of structures of transistors capable of being integrated into the other region of the substrate adjacent to that modified to limit the flow of stray voltages.

FIGS. 8A, 8B, 8C, 8D, 8E, 8F, 8G, 8H, 9 and 10 are used to illustrate an example of a method for creating a circuit with several levels of superimposed transistors and formed on a bulk substrate locally modified for RF uses.

FIGS. 11A, 11B and 11C are used to illustrate various steps of creating a trapping layer located on a bulk substrate and juxtaposed with a region of the bulk substrate in which transistors of a first level of transistors are formed.

FIG. 12 is used to illustrate a creation of contacts by siliconization of transistors of the lower level.

FIG. 13 is used to illustrate an exemplary embodiment of a structure for blocking stray voltages formed by an alternation of blocks of dielectric material having positive charges and blocks of dielectric material having negative charges.

FIGS. 14A and 14B are used to illustrate various steps of a structure for blocking stray voltages formed by an alternation of N-doped zones and P-doped zones.

FIG. 15 is used to illustrate a step of assembly between a structure comprising a first level of transistors created on a bulk substrate and above which one or more ground plane zones for upper-level transistors are formed and a support provided with a semiconductor layer in which these upper-level transistors are capable of being formed.

Identical, similar or equivalent parts of the various figures bear the same numerical references so as to facilitate the transition from one figure to another.

The various parts shown in the drawings are not necessarily shown according to a uniform scale, to make the drawings more readable.

Furthermore, in the description below, terms that depend on the orientation of a structure such as “front”, “rear”, “upper”, “lower”, “on”, “under”, “top”, “bottom”, “above”, “below” apply when considering that the structure is oriented as illustrated in the drawings.

### DETAILED DISCLOSURE OF SPECIFIC EMBODIMENTS

Reference is now made to FIG. 1 in which an example of a “3D” integrated circuit with several superimposed stages or levels N₁, N₂ of transistors is shown.

The circuit is here formed from a bulk semiconductor substrate, for example made of silicon, in particular an HR (HR for “Highly Resistive”) substrate, provided with at least one semiconductor layer with a high resistivity, that is to say greater than 100Ω·cm and preferably greater than 1 kΩ·cm.

The circuit comprises a lower level N₁ with at least one transistor T₁₁, in particular a transistor of a first type, for example of the bipolar type, advantageously of the heterojunction bipolar type (HBT). This transistor can be at least partially formed in a surface semiconductor layer 12 of the substrate 10 for example made of silicon and/or at least partially formed in a semiconductor layer disposed on and in contact with the surface semiconductor layer 12 of the substrate 10. In the specific case in which the transistor T₁₁ is a heterojunction bipolar transistor (HBT), a layer of SiGe having a germanium concentration gradient can be formed to create the base region of the transistor.

According to another embodiment, the transistor T₁₁ can be an HEMT (for “high-electron-mobility transistor”) transistor, formed in particular from at least one layer containing gallium nitride (GaN) arranged on a substrate made of silicon.

The transistor T₁₁ of the first type is located here in a first region R1 distinct from a second region R₂ of the substrate 10 by its composition.

It is also possible to form CMOS transistors in the first region R₁.

The integrated circuit is here provided with at least one RF circuit or RF module and the substrate 10 comprises a particular structure 50, located in the second region R2. This structure 50 is configured to limit surface stray conduction phenomena capable of being generated by the RF circuit, in particular when it conveys signals having a high frequency, for example greater than 2 GHZ.

The localized structure 50 can comprise a charge-trapping layer 23, commonly called “trap-rich”, formed by a semiconductor material rich in crystalline defects and/or grain joints. In this case, the charge-trapping layer 23 is typically a layer made of polycrystalline semiconductor material, for example polycrystalline silicon (polySi). A layer 23 of polySi with a thickness for example between 10 nm and 3 μm, advantageously between 50 nm and 300 nm can for example be provided. The charge-trapping layer 23 can advantageously be formed by a semiconductor material rich in implantation defects.

For example, the trapping layer 23 can be formed using steps of a method as described in the document EP3840033A1 coming from the applicant or the document “Defect Engineering for Enhanced Silicon Radiofrequency Substrates”, Perrosé et al., physica status solidi (a) Volume 221, Issue 17: Special Issue: Gettering and Defect Engineering in Semiconductor Technology, 2024.

The structure 50 extends over a part of the substrate 10 opposite which the RF circuit is provided, such a circuit being typically provided with at least one RF component of the antenna or inductance type and a switch circuit typically made from transistors of the MOS type.

This heterogeneous arrangement of the bulk substrate 10 with regions R1, R2 having different compositions allows in particular to be able to integrate certain types of transistors particularly adapted to bulk substrates while optimizing the performance with respect to the RF circuit.

The structure for trapping charges and/or blocking stray voltages formed in the second region R₂ does not extend on the first region R₁ and in the first region R₁ of the substrate 10, the device, and in particular the transistor(s) T₁₁ of the first level N₁ of transistor(s) located in or opposite the first region R₁ is not in contact with the structure for trapping charges and/or blocking stray voltages formed in the second region R₂. Thus the transistor(s) T₁₁ is or are surrounded by portions lacking a structure for trapping charges and/or blocking stray voltages.

Thus in the exemplary embodiment illustrated in FIG. 1, the transistor T₁₁ of the first type is entirely electrically isolated from the structure for trapping charges and/or blocking stray voltages 50. The transistor T₁₁ is thus surrounded by a portion devoid of a structure for trapping charges and/or blocking stray voltages.

The integrated circuit is also provided with at least one second level N₂ of transistors, disposed on the first level N₁, and the respective channel regions of which extend in a second semiconductor layer 112, for example made of silicon. The second semiconductor layer 112 is advantageously a layer with a small thickness, typically less than 500 nm and for example between 10 nm and 500 nm, preferably between 100 nm and 10 nm. Such a layer is particularly adapted to the implementation of partially or fully depleted transistors. The second semiconductor layer 112 can be formed by transfer, and in particular by molecular adhesion bonding, of a support onto a stack of layers covering the substrate 10. The second semiconductor layer 112 can for example be a layer of a support of the semiconductor on insulator type. Such a support is typically formed by a semiconductor support layer, coated with an insulating layer typically made of silicon oxide and commonly called “BOX”, the insulating layer itself being coated with the semiconductor layer 112. According to a specific implementation possibility, the second semiconductor layer 112 can contain a semiconductor material different from that of the substrate 10.

The first level N₁ of transistor(s) T₁₁ and the second level N₂ of transistor(s) are separated by a stack or at least one “inter-level” ILD (acronym for “Inter-Layer Dielectric”) insulating layer 35 for example containing silicon oxide (SiO₂).

An insulating thickness H1 between the second semiconductor layer 112 and the charge-trapping layer 23 preferably of at least 5 nm, in particular between 5 nm and 1 μm for example approximately 200 nm, can be provided.

An insulating thickness H2 between the first level N₁ of transistors and the semiconductor layer 112 for example between 5 nm and 1 μm, for example approximately 100 nm can also be provided.

Thus, as illustrated in FIG. 1, the lower-level transistor T₁₁ is here entirely separated from the semiconductor layer 112 dedicated to the second-level N₂ transistors via the non-zero insulating thickness H2.

The first level N₁ of transistor(s) T₁₁ and the second level N₂ of transistor(s) are thus separated from one another by a non-zero distance equal to H2 (measured in a plane orthogonal to a main plane of the substrate 11).

The second level N₂ of transistors comprises at least one transistor T₂₁, of a type different from that of the lower-level transistor T₁₁, for example a MOS transistor. The transistors T₁₁, T₂₁ are here formed in distinct stacks of layers.

Via its thickness and the manner in which it is created, the semiconductor layer 112 for the upper stage N₂ is particularly adapted to the creation of CMOS or MOS transistors, in particular MOS with a partially depleted or fully depleted channel.

Thus, it is possible for example to form MOS or CMOS transistors in a semiconductor layer 112 of the upper level N₂ while bipolar transistors are formed in the bulk substrate 10 of the lower level N₁.

Providing transistors of a given type and according to a given technology in one level and transistors of a different type and according to a technology different from the given technology in another level can also allow to simplify the method for manufacturing the circuit and reduce the manufacturing costs. However, it is alternatively possible to co-integrate transistors of different types and/or having different structures, within the same level N₁, N₂.

In the specific exemplary embodiment illustrated in FIG. 1, an upper-level N₂ transistor T₂₁ is for example a switching transistor of the RF circuit disposed opposite the region R₂ and the charge-trapping layer 23. Providing transistors of the RF circuit opposite the structure 50 and in particular the charge-trapping layer 23 allows to improve the performance of this circuit.

Advantageously, the transistor T₂₁ can have a partially depleted channel, for example a switching MOS transistor made using PDSOI (acronym for “Partially Depleted Silicon-On-Insulator”) technology.

The transistors T₁₁, T₂₁ are provided with conductive pads 148a and 149a, 149b, 149c, respectively.

Like in the specific exemplary embodiment illustrated in FIG. 1, the transistors T₁₁, T₂₁ of different levels N₁, N₂ can be connected to each other via a conductive line 151 of a first metal level M₁ connecting respective pads 148a and 149a of the transistors T₁₁, T₂₁.

The second level N₂ of transistor(s) T₂₁ is covered with k (with k an integer greater than 1) metal interconnection stages M₁, . . . , Mₖ, each stage being provided with one or more metal lines and via(s) formed in one or more insulating layer(s) 175 for example made of SiO₂.

In the specific exemplary embodiment of FIG. 1, a component Cₖ of the RF circuit, in the form of an antenna, is created in a “BEOL” (acronym for “Back-End Of Line”) stage here along with a metal line of a k^{th} metal interconnection level Mₖ, wherein k can be for example equal to 10.

The component Cₖ is disposed opposite the localized structure 50 to allow to limit the stray conduction and in particular eddy currents capable of being generated by RF signals conveyed by the antenna.

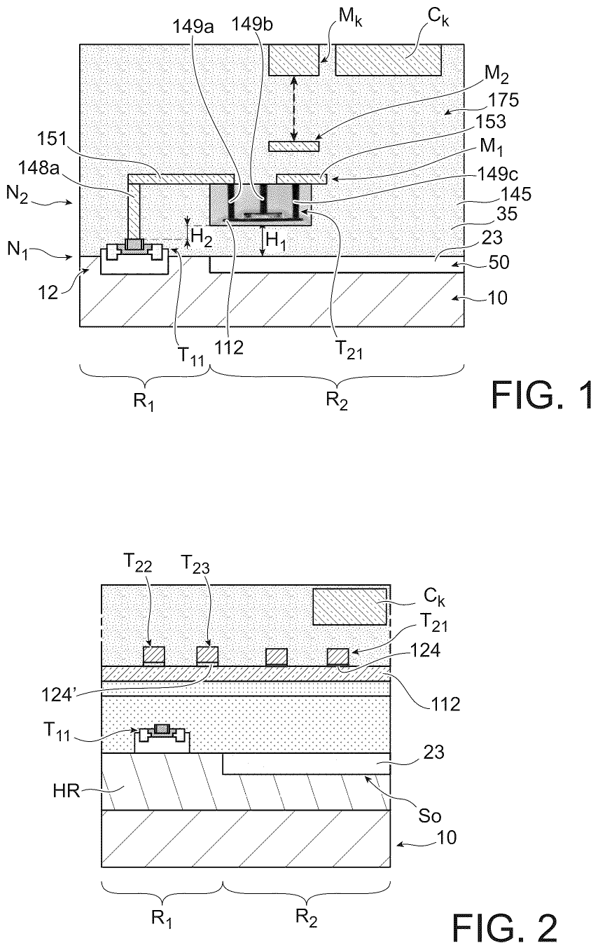

In another exemplary embodiment illustrated in FIG. 2, the second level N₂ of transistors comprises transistors T₂₂, T₂₃, the channel region of which is formed in the upper semiconductor layer 112, but which are located this time opposite the first region R₁ of the substrate 10 devoid of a charge-trapping layer and in which the transistors of the lower level N₁ are provided.

It is also possible to co-integrate transistors having various thicknesses of dielectric. Thus, the transistors T₂₂, T₂₃ have, in this specific exemplary embodiment, a thick gate dielectric 124, for example twice as thick as the dielectric of other transistors or as the standard thickness. As an alternative to the illustrated example, it is also possible to provide such transistors with thicker dielectric above the second region R2.

In an alternative embodiment of an integrated circuit as described above, one or more “rear” electrodes arranged between the substrate 10 and the semiconductor layer 112 in which the respective channel regions of the transistors of the upper level N₂ extend can be provided.

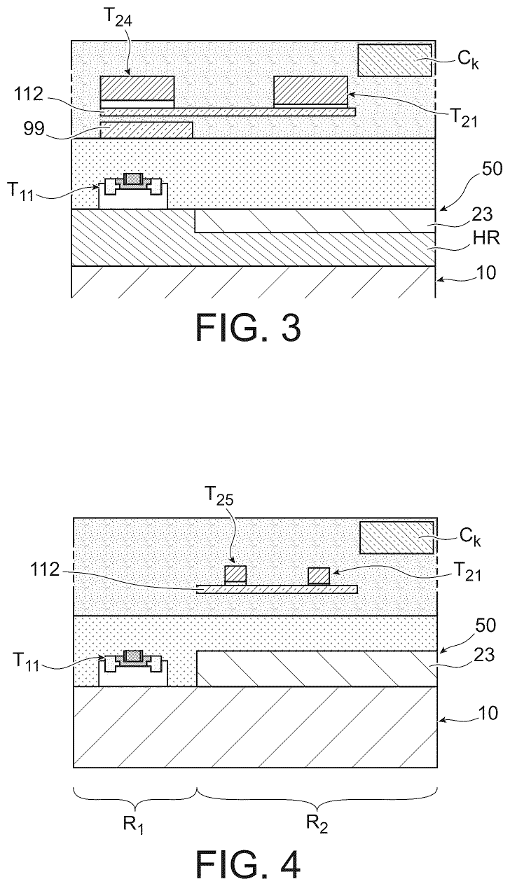

A specific exemplary embodiment, illustrated in FIG. 3, provides as a rear electrode a conductive zone 99 forming a ground plane, for example containing a doped semiconductor material such as doped silicon or containing a metal material for example such as TiN.

Such a rear electrode, besides the possibility of being used as a ground plane or a means for modulating the threshold voltage of a transistor T₂₄ located above it, can also be used as a screen for potentials or potential variations of the lower level, for example of the lower-level transistor T₁₁.

According to one possible embodiment illustrated in FIG. 4, instead of being entirely formed in the thickness of a bulk substrate 10, for example by amorphization implantation then annealing, the charge-trapping layer 23 can be formed by depositing on the region R₂ of the substrate 10 a layer of amorphous or polycrystalline semiconductor material, then optional subsequent treatment, for example using a laser, so as to create and/or enrich it with crystalline defects or grain joints. The charge-trapping layer 23 can then form an extra thickness for example between 10 nm and 1 μm, on the substrate 10, and in particular on a highly resistive surface layer of this substrate 10.

The localized structure 50 allowing to limit surface stray conduction can, as an alternative to a charge-trapping layer, be formed by a succession of junctions made in the region R₂ of the substrate 10.

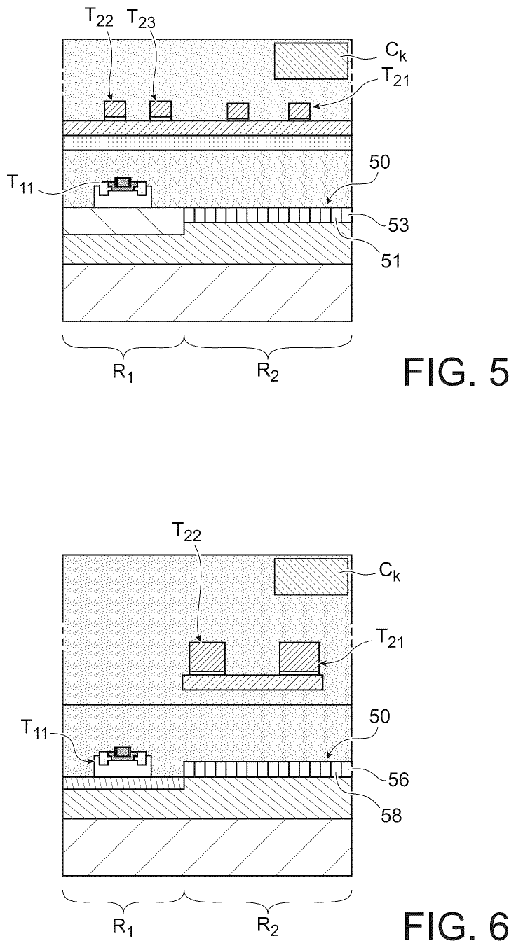

Thus, in the exemplary embodiment illustrated in FIG. 5, the localized structure 50 is formed by an alternation of doped regions 51 doped according to a doping of a first type, in particular N or P, and doped regions 53 doped according to a doping of a second type opposite to the first type, in particular P when the doping of the regions 51 is of the N type, or in particular N when the doping of the regions 51 is of the P type. An example of implementation of such a structure is given in the document EP3882971A1 from the applicant.

According to another exemplary embodiment illustrated in FIG. 6, the localized structure 50 configured to limit the parasitic phenomena of surface conduction in the substrate 10 can be formed by an alternation of dielectric blocks made of a dielectric material 56 with positive fixed charges and dielectric blocks made of a second dielectric material 58 with negative fixed charges. “Dielectric material with positive fixed charges” means here a material capable of comprising positive fixed charges without external biasing being necessary. Likewise, “dielectric material with negative fixed charges” means here a material capable of comprising negative fixed charges without external biasing being necessary. Via this alternation of dielectric materials, an alternation of polarity of charges is created in order to block the circulation of a stray voltage in the region R₂ of the substrate 10. The dielectric material with positive fixed charges can for example advantageously be chosen from the following materials: silicon oxide, in particular SiO₂, silicon nitride, silicon oxycarbide. The dielectric material with negative fixed charges can, for example, contain alumina, in particular Al₂O₃ or hafnium oxide, in particular HfO₂. Such dielectric blocks 56, 58 can be formed for example by depositions and etchings so as to form an extra thickness on a substrate 10 zone which is juxtaposed with a region R1 of the substrate 10 in which transistors of the first level are disposed. An exemplary embodiment of such a structure is given in the document EP4297074A1 from the applicant.

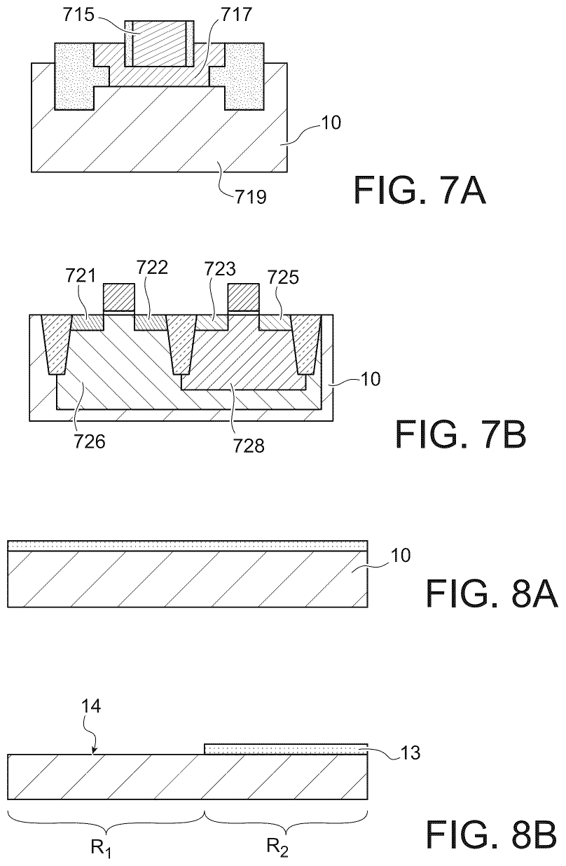

In FIGS. 7A-7B, various examples of structures of transistors capable of being formed in the region R1 of the bulk substrate 10 for the lower level N1 of the integrated circuit are given.

In the exemplary embodiment of FIG. 7A, a transistor is created in the bulk substrate 10, the collector, base and emitter regions of the bipolar transistor of which are this time formed respectively by regions 719, 717, 715 superimposed and doped respectively according to a doping of a first type, for example N-doped, according to a doping of a second type, for example P-doped, and according to a doping of the first type for example N-doped, so as to form here an NPN arrangement.

Advantageously, the collector and emitter regions can be formed from silicon, while the base region is made of SiGe with a germanium concentration gradient from the collector to the emitter. A germanium concentration gradient in the base region can in particular be provided in order to make the band gap narrower at the collector than at the emitter. Such a narrowing of the band gap allows to accelerate the transport through the base and obtain an improved frequency response.

A specific exemplary embodiment of a heterojunction bipolar transistor is given in the document “SiGe HBTs Featuring fT >400 GHz at Room Temperature” by Geynet et al., 2008 IEEE Bipolar/BiCMOS Circuits and Technology Meeting.

In another exemplary embodiment illustrated in FIG. 7B, an NMOS transistor formed by doped source and drain regions 721, 722 in a well 726 more weakly doped according to a doping of the opposite type, for example P—, as well as a PMOS transistor formed by doped source and drain regions 723, 725 in a well 728 weakly doped according to a doping of the opposite type, for example N—, are created in the substrate 10.

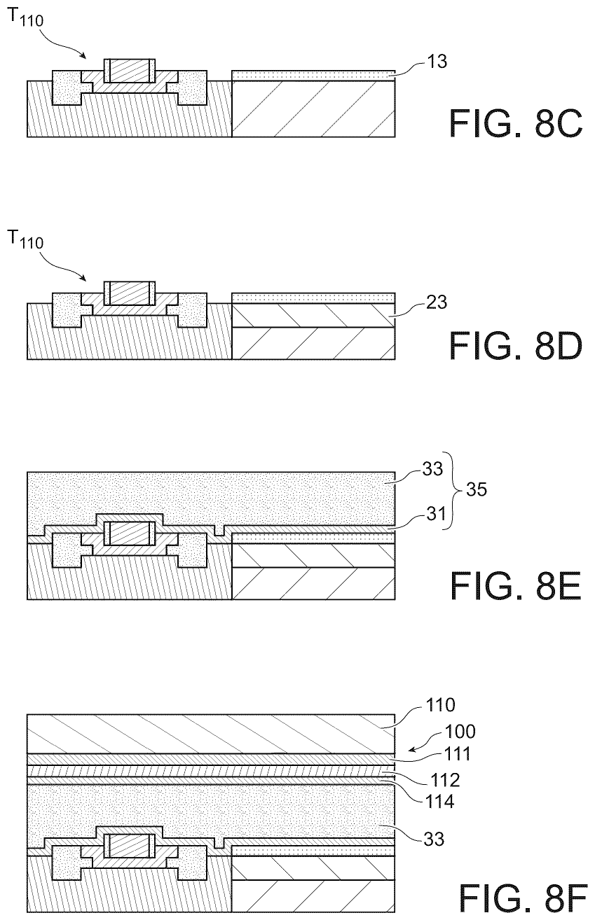

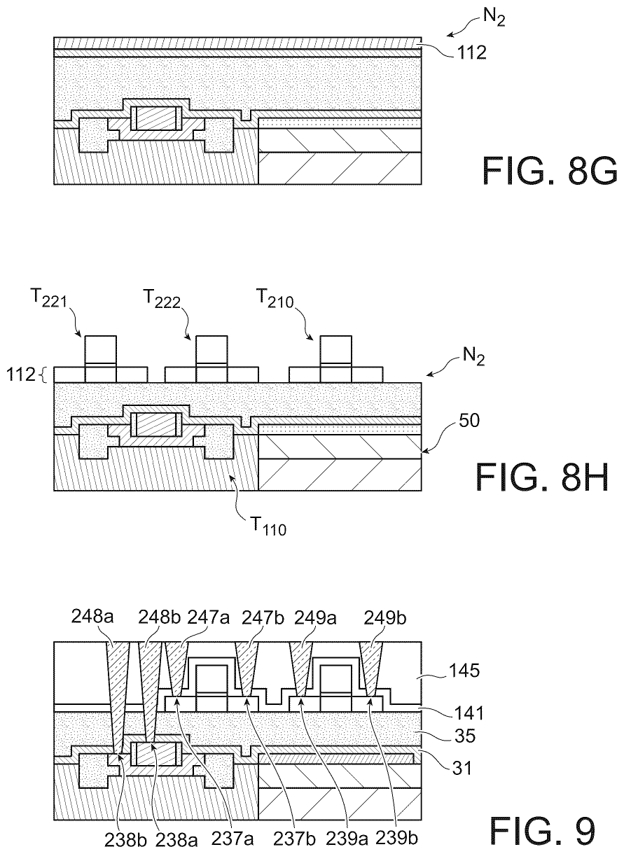

An example of a method for creating an integrated circuit with superimposed levels of transistors on a bulk substrate and provided with a localized structure for trapping charges and/or blocking stray voltages will now be described in connection with FIGS. 8A-8H.

A possible starting structure for the implementation of such a method is given in FIG. 8A, in the form of a bulk substrate 10 for example a substrate made of silicon and highly resistive (HR) or provided with at least one semiconductor layer having high resistivity, i.e. greater than 500Ω·cm.

A masking 13 located opposite a region R2 of the substrate 10 is then created, while preserving an opening 14 exposing another region R1 of the substrate 10.

According to a specific exemplary embodiment given in FIGS. 8A-8B, the masking 13 can be formed by a layer deposited “full wafer”, in other words over the entire extent of the substrate 10, then etched locally so as to expose the region R1. For example, the masking 13 can be made of silicon oxide. In this case, such masking 13 can be created for example by thermal oxidation of the substrate 10. A thickness of oxide for example between 20 nm and 500 nm for example approximately 150 nm can be provided.

The masking layer 13 is then etched. For this, typically it is coated with a layer of resin in which patterns are formed by photolithography. The pattern(s) are then transferred by etching into the masking layer. This etching can for example be dry etching using a plasma, for example such as a plasma containing fluorocarbon gas, for example containing CF₄, C₂H₆, CHF3 and which can possibly be combined with CH₄.

The masking 13 (and if applicable the layer of resin not shown) covering it is (are) dimensioned, in particular in terms of thickness, to allow to prevent diffusion of dopants in the substrate 10 during subsequent doping steps carried out to form transistors in the region R1 of the substrate 10 exposed by the opening 14. The thickness of the masking 13 depends in particular on the thermal budget for producing this or these transistors. For example, 150 nm of thermal oxide can be provided.

One or more transistors are then formed, in particular transistors of a first type in the region R1 of the substrate 10. The region R1 can for example be dedicated to bipolar transistors and these transistors are produced in particular via steps of doping by implantation or in-situ doped epitaxies to form doped regions and in particular PN junctions of the bipolar transistor.

Thus, in the specific exemplary embodiment given in FIG. 8C, a transistor T₁₁₀ created in the substrate 10 has a structure of the type described above in connection with FIG. 7A.

The masking 13 thus allows to protect the region R2 of the substrate 10 from these implantation steps and to keep it dopant-free or at least to preserve it as a region of high resistivity.

A structure 50 is then created opposite the region R₂ of the substrate 10 to limit stray conduction.

Such a structure 50 can be, like in the exemplary embodiment of FIG. 8D, in the form of a charge-trapping layer 23 arranged under the masking 13.

Such a charge-trapping layer 23 rich in crystalline defects and/or grain joints can in this case be formed for example using at least one step of implantation and/or amorphization of the substrate 10. When carrying out an amorphization implantation, the implantation dose and energy can be determined by using tools for example such as SRIM (acronym for “Stopping and Range of Ions in Matter”) or TRIM (“Transport of Ions in Matter”) that allow to model the ion implantation interaction with various materials.

An amorphization implantation is carried out under the masking 13 for example using heavy ions formed from Si or Ge, or from F according to a dose for example of approximately 10¹⁵ at/cm². The thickness of amorphous material, in particular of silicon made amorphous, can be for example between 5 nm and 500 nm, preferably between 5 nm and 50 nm.

A recrystallization annealing is then carried out, having a duration and a temperature provided so as to transform the semiconductor material rendered amorphous into a material rich in crystalline defects and/or grain joints. The annealing can advantageously be provided in terms of time and temperature to allow to transform the semiconductor material rendered amorphous into a polycrystalline material. For example, rapid annealing, i.e. having a duration of less than 10 seconds and advantageously less than 2 seconds at a high temperature preferably greater than 800° C. but less than 1400° C. can be carried out so as to transform amorphous Si into polycrystalline Si.

The formation of a polycrystalline semiconductor can also be implemented using a laser treatment. A laser with a wavelength between 20 nm and 400 nm with pulse durations typically shorter than one microsecond and for example of approximately one to several hundred nanoseconds can in particular be used.

Another example provides a layer of crystalline defects created by implantation, for example using He like in the document: “Defect engineering for enhanced silicon radiofrequency substrates” by M. Perose in Phys. Status Solidi A 2024, 221, 2400215 or by creating deep defects with for example metal species like in the document “Deep Level Impurity Engineered Semi-Insulating Cz-Silicon as Microwave Substrates” by K. Mallik in Proceedings of the 6th European Microwave Integrated Circuits Conference 2011.

Then (FIG. 8E), the assembly is covered with at least one insulating layer and typically with an “inter-level” insulating stack 35. Such an insulating stack 35 can comprise an insulating contact etch-stop layer (CESL) 31, for example made of silicon nitride, and having a thickness which can be for example between 10 nm and 60 nm.

This insulating layer 31 is then coated with another insulating layer 33 of the PMD (for “Pre Metal Dielectric”) type typically made of an insulating material different from that of the CESL layer 31. The other insulating layer 33 is for example made of silicon oxide and can be provided with a thickness for example between 100 nm and 1 μm.

Then, the substrate 10 coated with the insulating stack 35 is assembled with another support provided with at least one semiconductor layer, preferably made of monocrystalline semiconductor material, for example monocrystalline silicon.

The assembly can be carried out by molecular adhesion bonding, also called “direct bonding”, where a free face of a surface layer of the support 100 is transferred directly onto a free face of the insulating stack 35. Molecular bonding of the oxide-on-oxide type can in particular be provided, the surface layer 114 then being made of silicon oxide, while the insulating stack 35 is also coated with a layer 34 of silicon oxide.

In the exemplary embodiment illustrated in FIG. 8F, the support 100 transferred onto the substrate 10 is of the semiconductor-on-insulator type. Such a support 100 is typically formed by a semiconductor support layer 110, for example made of silicon, coated with an insulating layer 111 typically made of silicon oxide and commonly called “BOX”, the insulating layer 111 being itself coated with a semiconductor layer 112, for example made of silicon, in which components and in particular transistors are intended to be at least partially formed.

The support layer 110 and the insulating layer 111 are then removed. This removal can be carried out in a conventional manner.

At the end of such a step, like in FIG. 8G, the semiconductor layer 112 in which a second level N₂ of components, in particular transistors, is provided is exposed. According to one possible implementation, the manufacturing of upper-level transistors can be preceded by a step of cutting the semiconductor layer 112 into several distinct portions in which active zones of transistors isolated from each other are provided. Such a step is typically carried out by photolithography, then etching.

Thus, in the exemplary embodiment of FIG. 8H, transistors T₂₂₁, T₂₂₂ are formed in portions 112a, 112b of the semiconductor layer 112 opposite the region R1 of the substrate 10 in which transistors of the first level N₁ are arranged. A transistor T₂₁₀ is formed in another portion 112c of the semiconductor layer 112. This other portion 112c is located opposite the region R₂ of the substrate 10 in which the localized structure 50 is formed. The transistors T₂₂₁, T₂₂₂ can for example be CMOS transistors, while opposite the localized structure 50, transistors of an RF circuit, in particular switching transistors, for example of the MOS type with a partially depleted channel, are typically formed. The creation of the transistors T₂₂₁, T₂₂₂, T₂₁₀ typically comprises in particular steps of depositing a gate dielectric of a gate material, etchings of these materials, doping to form source and drain regions.

The second level N₂ of transistors is then covered with one or more insulating layers, for example an insulating stack 145 comprising an insulating contact etch-stop layer (CESL) 141, for example made of silicon nitride and a thicker insulating layer 143 for example made of silicon oxide.

Conductive pads 248a, 248b, 247a, 247b, 249a, 249b are then formed on the transistors T₂₂₁, T₂₂₂, T₂₁₀.

To create such pads, one or more holes passing through the insulating layers 141, 145, 33, 31 and exposing at least one lower-level N₁ transistor T₁₁₀ and one or more holes passing through the insulating layers 141, 145 and exposing at least one upper-level transistor T₂₂₁, T₂₂₂ are typically formed.

The filling of holes with a conductive material is typically preceded by at least one step of siliconization of semiconductor regions exposed via the bottom of the holes or certain holes to form contacts 238a, 238b, 237a, 237b, 239a, 239b. Such a siliconization typically comprises a deposition of metal material, for example Ni, then a heat treatment so as to form siliconized areas containing metal alloy and semiconductor. For example, the siliconization can be carried out by deposition of nickel then heat treatment for example at a temperature of approximately 400° C.

To improve the performance of the lower-level transistor(s), it is alternatively possible to advantageously create the contacts 238a, 238b of the lower-level N₁ transistor(s) before the semiconductor layer 112 is transferred and before the complete formation of the stack 35 onto which this semiconductor layer is transferred.

One or more metal interconnection layers M1, . . . , Mₖ are then formed in a new stack of insulating layers.

The second level N₂ of transistor(s) is thus covered with k levels of metal interconnections, each stage being formed in one or more insulating layers for example made of SiO₂ and being provided with one or more metal lines. Concomitantly with the formation of at least one metal interconnection level, it is possible to create passive components, and in particular passive components for an RF circuit also called RF components.

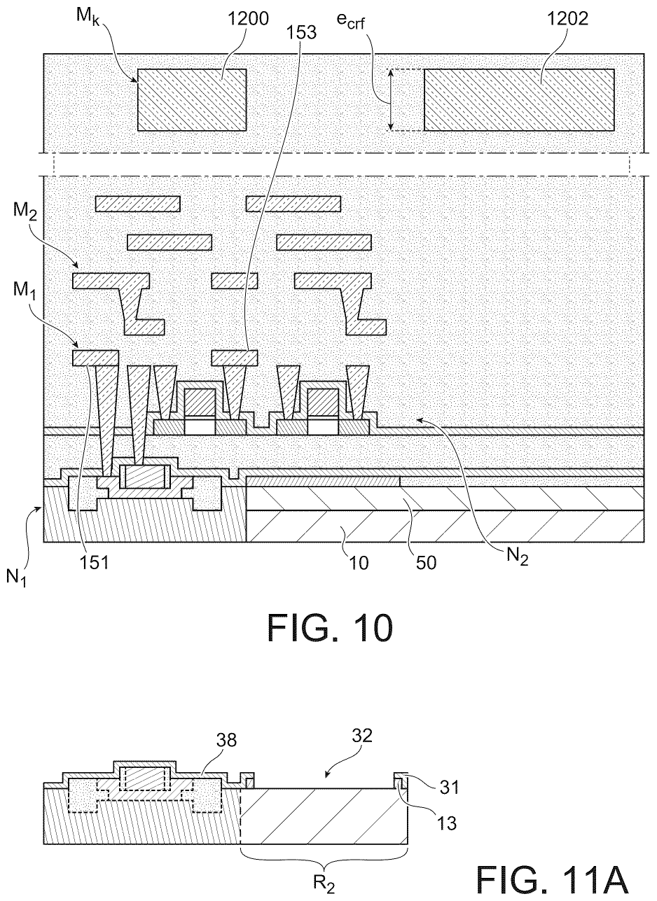

Thus, in the example illustrated in FIG. 10, a metal line 1200, for example made of copper and dedicated to an interconnection, and an antenna 1202 also made of copper, are created in the same k^{th} level. The antenna 1202 is disposed opposite the localized structure 50 to allow to limit a stray conduction and in particular eddy currents capable of being generated when this antenna conveys an alternating RF signal, for example with a frequency greater than 2 GHz. The RF component(s), here for example the antenna 1202, can be provided in a “thick” metal level, with a thickness e_{crf} typically of at least 1 μm and for example between 0.5 μm and 5 μm.

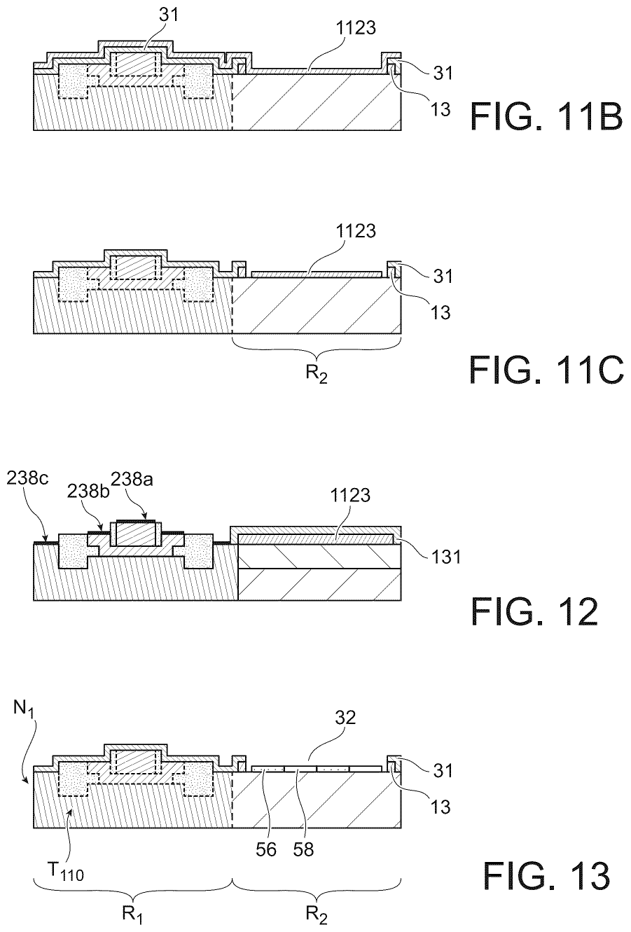

An alternative embodiment of the localized structure 50 in the form of a charge-trapping layer is illustrated in FIGS. 11A-11C.

For this alternative, after forming the first level N₁ of transistor(s) T₁₁₀ and covering the assembly with at least one insulating layer 31, such as an insulating contact etch-stop layer (CESL) 31, for example made of silicon nitride, a passage is made through this insulating layer 31 and the masking, so as to expose the region R₂ of the substrate 10 disposed under this masking 13 (FIG. 11A).

A layer 1123 of amorphous or polycrystalline semiconductor material, for example amorphous silicon or polycrystalline silicon, is then deposited (FIG. 11B) in the passage 32 so as to cover at least a portion of the region R2 of the substrate 10.

An etching, for example using SF₆, of the layer 1123 of amorphous or polycrystalline semiconductor material is then carried out (FIG. 11C) so as to preserve a portion of the layer 1123 in the passage 32 and opposite the region R2 of the substrate 10. Thus, instead of creating the charge-trapping layer via an implantation to form a polycrystalline material, this layer can be formed by deposition.

According to another alternative embodiment, the charge-trapping layer can be created after partially forming the first level N₁ of transistor(s) T₁₁₀ but before creating contacts 238c, 238b, 238a for the first-level N₁ transistor(s). Thus, in the exemplary embodiment given in FIG. 12, after having formed the collector, emitter, base regions of the transistor(s) T₁₁₀, a trapping layer 1123 is formed for example by deposition of polysilicon. Then, after forming a protective for example insulating layer 131 on the trapping layer 1123, the siliconization is carried out on the accesses 238c, 238b, 238a.

Another alternative embodiment of the localized structure 50 is illustrated in FIG. 13.

For this alternative, after forming the first level N₁ of transistor(s) T₁₁₀ and covering the assembly with at least one insulating layer 31, such as an insulating contact etch-stop layer (CESL) 31, for example made of silicon nitride, a passage 32 is made through this insulating layer 31 and the masking, so as to expose the region R2 of the substrate 10 disposed under this masking 13.

According to one possible implementation, a layer of dielectric 56 with positive fixed charges or of dielectric 58 with negative fixed charges is first deposited in the passage 32. The dielectric material with positive fixed charges can for example advantageously be chosen from the following materials: silicon oxide, in particular SiO₂, silicon nitride, silicon oxycarbide. The dielectric material with negative fixed charges can, for example, contain alumina, in particular Al₂O₃ or hafnium oxide, in particular HfO₂. Distinct blocks are then formed in this material 56 or 58.

Then, another layer of dielectric 58 with negative fixed charges (in the case in which blocks of dielectric material 56 with positive fixed charges have just been formed) or of dielectric 56 with positive fixed charges (in the case in which blocks of dielectric material 58 with negative fixed charges have just been formed) is deposited and this other layer is etched so as to form other blocks and thus an alternation of blocks of dielectric 56 with positive fixed charges and blocks of dielectric 58 with negative fixed charges.

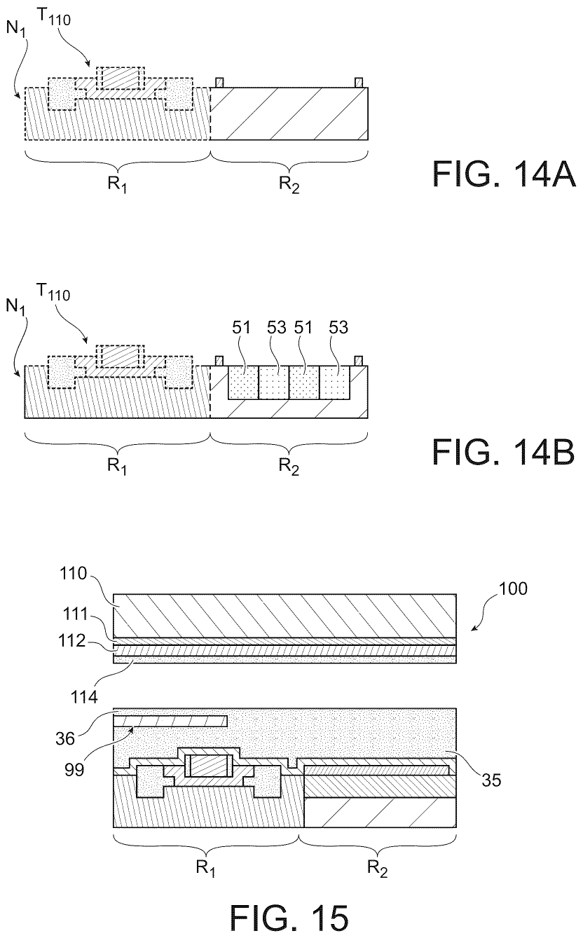

According to another alternative embodiment illustrated in FIGS. 14A-14B, after forming the transistors in the region R1 of the substrate 10, a set of zones 51 doped according to a first type of doping, for example P, is formed using one or more implantations of a region R2 of the substrate 10. Then, another set of zones 53 doped according to a second type of doping different from the first type of doping is created, for example by implantation of the region R2 of the substrate, the doped zones 51, 53 being distributed so as to create a plurality of juxtaposed PN junctions.

As indicated above, according to a specific embodiment of the integrated circuit made on a bulk substrate 10 and with superimposed levels N₁, N₂ of transistors, one or more rear electrodes are provided to control transistors of the upper level. In the illustrated exemplary embodiment, a rear electrode is for example formed by a metal zone 99 for example made of TiN or made of doped semiconductor material. It can be created before assembly of the substrate 10 coated with the first level N₁ of transistors with a support 100 as described above and comprising a semiconductor layer 112 for the upper-level N₂ transistors.

Thus, in the exemplary embodiment illustrated in FIG. 15, the ground plane zone 99 is formed in the inter-level insulating stack 35, and can be coated with an additional insulating layer 36, for example made of silicon oxide, to allow the molecular adhesion bonding with an insulating layer 114 for example made of silicon oxide of the support 100, and carry out a dielectric separation with the upper-level semiconductor layer 112.

1-15. (canceled)

16. An integrated circuit formed on a bulk semiconductor substrate, comprising:
a bulk semiconductor substrate;
a lower level of transistors including, opposite a first region of the bulk semiconductor substrate, at least one lower-level transistor formed at least partially in a first semiconductor layer, the first semiconductor layer being part of the bulk semiconductor substrate or disposed on and in contact with the bulk semiconductor substrate;
an upper level of transistors including at least one upper-level transistor having a channel region formed in a second semiconductor layer included in a stack of layers resting on the bulk semiconductor substrate, the at least one upper-level transistor being disposed opposite a second region of the bulk semiconductor substrate different from the first region;
a localized structure configured to trap electrical charges and/or block stray voltages, the localized structure being formed on or in the second region of the bulk semiconductor substrate and configured to limit stray voltage in the second region, the localized structure being located beneath the at least one upper-level transistor;
one or more metal interconnection levels; and
at least one radio-frequency component formed in one of the metal interconnection levels, the radio-frequency component comprising an antenna or an inductance and being arranged opposite the localized structure.

17. The integrated circuit of claim 16, wherein the localized structure is formed on or in the second region of the bulk semiconductor substrate such that the at least one lower-level transistor is not in contact with the localized structure.

18. The integrated circuit of claim 16, wherein the at least one lower-level transistor comprises a transistor of a first type selected from a bipolar transistor or a high electron mobility transistor, and wherein the at least one upper-level transistor comprises a metal-oxide-semiconductor transistor.

19. The integrated circuit of claim 16, wherein the at least one upper-level transistor is part of a switch circuit disposed opposite the second region and not extending opposite the first region.

20. The integrated circuit of claim 16, wherein the localized structure comprises at least one element selected from the group including:
a semiconductor layer including implantation defects;
a layer of amorphous semiconductor material or polycrystalline semiconductor material;
a plurality of junctions formed by an alternation of regions doped with a first conductivity type and regions doped with a second conductivity type different from the first conductivity type; and
a heterogeneous dielectric region comprising an alternation of dielectric blocks having positive fixed charges and dielectric blocks having negative fixed charges.

21. The integrated circuit of claim 16, further comprising at least one additional upper-level transistor disposed opposite the first region, the additional upper-level transistor including a rear electrode or ground plane arranged within the stack of layers between the first region and the additional upper-level transistor.

22. A method for manufacturing the integrated circuit of claim 16, comprising:
providing a highly resistive bulk semiconductor substrate;
forming, opposite a first region of the bulk semiconductor substrate, at least one lower-level transistor having a channel formed in a semiconductor layer of the bulk semiconductor substrate or disposed in contact with the bulk semiconductor substrate;
forming, opposite a second region of the bulk semiconductor substrate different from the first region, a localized structure configured to trap charges and/or block stray voltages so as to limit stray conduction in the second region;
covering the lower-level transistor and the localized structure with at least one inter-level insulating layer;
assembling a support onto the inter-level insulating layer, the support including a second semiconductor layer; and
forming at least one upper-level transistor from the second semiconductor layer, the upper-level transistor having a channel region in the second semiconductor layer and being disposed opposite the second region of the bulk semiconductor substrate.

23. The method of claim 22, wherein forming the at least one lower-level transistor includes one or more processing steps performed prior to forming the localized structure.

24. The method of claim 22, further comprising forming a masking layer on the second region to protect the second region while leaving an opening opposite the first region, wherein the at least one lower-level transistor is at least partially formed within the opening.

25. The method of claim 22, further comprising:
forming at least one layer covering the at least one lower-level transistor; and
forming a passage through the at least one layer to expose at least a portion of the second region,
wherein the localized structure is formed on or in the exposed portion of the second region through the passage.

26. The method of claim 25, wherein forming the localized structure comprises:
depositing a layer of amorphous semiconductor material or polycrystalline semiconductor material within the passage so as to cover the exposed portion of the second region; and
etching the deposited layer to retain at least a portion of the amorphous or polycrystalline semiconductor material opposite the second region.

27. The method of claim 25, wherein the localized structure comprises a heterogeneous dielectric region including an alternation of dielectric blocks having positive fixed charges and dielectric blocks having negative fixed charges, and wherein forming the localized structure comprises:
depositing a first dielectric material having fixed charges of a first polarity within the passage;
etching the first dielectric material to form blocks of the first dielectric material; and
depositing a second dielectric material having fixed charges of an opposite polarity to form blocks of the second dielectric material between the blocks of the first dielectric material.

28. The method of claim 25, wherein forming the localized structure comprises forming a plurality of juxtaposed junctions by alternately doping regions of the second region with a first conductivity type and a second conductivity type different from the first conductivity type through successive implantation steps performed through the passage.

29. The method of claim 24, wherein forming the localized structure comprises implanting dopants to form a layer rich in crystalline defects in a portion of the bulk semiconductor substrate located beneath the masking layer.

30. The method of claim 22, further comprising, prior to assembling the support onto the inter-level insulating layer:
forming one or more ground plane regions on the inter-level insulating layer; and
covering the one or more ground plane regions with at least one bonding insulating layer,
wherein assembling the support onto the inter-level insulating layer comprises molecular adhesion bonding of the bonding insulating layer to the support.
